(19) United States
(12) Patent Application Publication
(10) Pub. No.: US 2017/0051400 A1
(43) Pub. Date: Feb. 23, 2017

(54) METHOD FOR MANUFACTURING A DOPED METAL CHALCOGENIDE THIN FILM, AND SAME THIN FILM

(71) Applicant: LG ELECTRONICS INC., Seoul (KR)

(72) Inventors: Minseok CHOI, Seoul (KR); Jinsan MOON, Seoul (KR); Mynghee JUNG, Seoul (KR); Taehyeong KIM, Seoul (KR)

(73) Assignee: LG ELECTRONICS INC., Seoul (KR)

(21) Appl. No.: 15/308,021

(22) PCT Filed: Apr. 22, 2015
(86) PCT No.: PCT/KR2015/004013

§ 371 Date: Oct. 31, 2016

(30) Foreign Application Priority Data
May 12, 2014 (KR) 10-2014-0056509

(51) Int. Cl. C23C 16/06; H01L 21/02; C23C 16/44

(52) U.S. Cl. CPC C23C 16/06; C23C 16/44; H01L 21/02568; H01L 21/0262

(57) ABSTRACT

The present invention relates to the manufacture of a hetero-element thin film and, particularly, to a method for manufacturing a doped metal chalcogenide thin film and the same thin film. The method for manufacturing a metal chalcogenide thin film of the present invention may comprise the steps of: supplying a first metal precursor that is gasified; supplying a second metal precursor that is gasified; supplying a chalcogen-containing gas; and reacting the first metal precursor, the second metal precursor, and the chalcogen-containing gas on a growing substrate at a first temperature condition to form a thin film.

### TECHNICAL FIELD

The present invention relates to manufacture of a heteroelement thin film, and particularly to a method of manufacturing a doped metal chalcogenide thin film and a thin film manufactured by the method.

### BACKGROUND ART

Among elements which belong to group 16 of the periodic table, five elements including oxygen (O), sulfur (S), selenium (Se), tellurium (Te) and polonium (Po) are referred to as oxygen group elements and, of the five, only three elements of sulfur, selenium and tellurium are referred to as sulfur group elements or chalcogens.

Oxygen and sulfur are representative non-metal elements, whereas other metals lose non-metallic properties and increase in metallic properties as atomic number increases. Selenium, tellurium and polonium are rare elements, whereas polonium is a naturally radioactive element.

Metal chalcogenide is a compound of a transition metal and chalcogen, which is a nanomaterial having a similar structure to graphene. Metal chalcogenide has a very small thickness corresponding to a thickness of an atomic scale layer, is thus flexible and transparent and has electrical properties such as semiconductor and conductor properties.

In particular, metal chalcogenide having semiconductor properties has a suitable band gap and electron mobility of hundreds of cm²/Vs, thus being applicable to semiconductor devices such as transistors and having great potential as flexible transistor devices.

MoS₂, WS₂ and the like, which are metal chalcogenide materials on which the most active research has been conducted, are capable of efficiently absorbing light due to direct band gap under a single layer condition and are thus suitable for application to optical devices such as optical sensors and solar cells.

A method of producing a metal chalcogenide nano thin film has been actively researched. However, there is a need for requirements of metal chalcogenide thin films for application to the devices, that is, methods of uniformly and continuously synthesizing large-area thin films.

Meanwhile, since a transition metal chalcogenide thin film having a layer structure has no dangling bond which extends outside the layer, doping is generally difficult and doping using plasma, ion implantation or the like may cause damage to the thin film.

Accordingly, there is a need for development of methods of forming doped transition metal chalcogenide thin films that do not cause damage to the thin films and impart excellent crystallinity to the thin films.

### DISCLOSURE

### Technical Problem

An object of the present invention devised to solve the problem lies in a method of manufacturing a metal chalcogenide thin film with high crystallinity and a thin film manufactured by the method.

### Technical Solution

The object of the present invention can be achieved by providing a method of manufacturing a doped metal chalcogenide thin film including supplying a gasified first metal precursor, supplying a gasified second metal precursor, supplying a chalcogen-containing gas, and reacting the first metal precursor and the second metal precursor with the chalcogen-containing gas on a growth substrate under a first temperature condition to form a thin film.

Here, the gasified first metal precursor and the gasified second metal precursor may be formed by heating a first metal powder and a second metal powder, respectively, or a mixture thereof.

In this case, the second metal powder may function as a dopant of the metal chalcogenide thin film and the doping concentration may be controlled by a molar ratio of the first metal powder and the second metal powder.

Here, the first metal precursor may include Mo or W, and the second metal precursor may include an n-type precursor including Tc and Re, or a p-type precursor including any one of V, Nb, Ta, Ti, Zr, Hf and Y.

Here, the first metal precursor may include V, Nb or Ta, and the second metal precursor may include an n-type precursor including any one of Mo, W, Tc and Re, or a p-type precursor including any one of Ti, Zr, Hf and Y.

Here, the first metal precursor may include Ti, Zr or Hf, and the second metal precursor may include an n-type precursor including any one of V, Nb, Ta, Mo, W, Tc and Re, or a p-type precursor including any one of Sc and Y.

Here, the first metal precursor may include Tc or Re, and the second metal precursor may include an n-type precursor including any one of Fe, Ru and Os, or a p-type precursor including any one of Mo, W, V, Nb, Ta, Ti, Zr and Hf.

Here, the method may further include conducting heat treatment under a second temperature condition higher than the first temperature condition.

In this case, the first temperature condition may be 300 to 850° C., and the second temperature condition may be 850 to 1,200° C.

In addition, the heat treatment may be carried out under a chalcogen-containing gas atmosphere.

Here, the chalcogen-containing gas may include at least one of S₂, Se₂, Te₂, H₂S, H₂Se, and H₂Te.

In another aspect of the present invention, provided herein is a method of manufacturing a doped metal chalcogenide thin film including supplying a gasified first metal precursor, supplying a gasified second metal precursor which belongs to a higher or lower Group on the periodic table than the first metal, supplying a chalcogen-containing gas, and reacting the first metal precursor and the second metal precursor with the chalcogen-containing gas on the growth substrate under a first temperature condition to form a thin film.

In yet another aspect of the present invention, provided herein is a doped metal chalcogenide thin film manufactured by the method described above.

### Advantageous Effects

First, because a metal chalcogenide thin film is formed by vapor reaction and a gas chalcogen source is used, a high-quality thin film can be obtained and synthesis of large-area uniform thin films is possible.

Metal chalcogenide material groups can be grown to a thickness which is stepwise controlled from a single layer to multiple layers by chemical vapor deposition and can be variably used according to application.

The doped metal chalcogenide thin film can be formed by mixing the first metal precursor with the second metal precursor, gasifying the mixture and reacting the gasified first and second metal precursors with a chalcogen-containing gas.

Accordingly, the substituted and doped high-quality metal chalcogenide thin film can be obtained.

In addition, as described above, a ratio between the first metal precursor and the second metal precursor can be easily controlled and the doping concentration can be easily controlled depending on the ratio.

### DESCRIPTION OF DRAWINGS

FIG. 1 is a schematic view illustrating an example of a process of manufacturing a doped metal chalcogenide thin film according to the present invention.

FIG. 2 is a schematic view illustrating another example of a process of manufacturing a doped metal chalcogenide thin film according to the present invention.

FIG. 3 is a graph showing an example of a process of forming a doped metal chalcogenide thin film according to the present invention.

FIG. 4 shows the location of elements for forming the metal chalcogenide thin film on the periodic table.

### BEST MODE

Reference will now be made in detail to the preferred embodiments of the present invention, examples of which are illustrated in the accompanying drawings.

However, the present invention allows various modifications and variations and specific embodiments thereof are exemplified with reference to the drawings and will be described in detail. The present invention should not be construed as limited to the embodiments set forth herein and includes modifications, equivalents and substitutions compliant with the spirit or scope of the present invention defined by the appended claims.

It will be understood that when an element such as a layer, area or substrate is referred to as being “on” another element, it may be directly on the element, or one or more intervening elements may also be present therebetween.

In addition, it will be understood that although terms such as “first” and “second” may be used herein to describe elements, components, areas, layers and/or regions, the elements, components, areas, layers and/or regions should not be limited by these terms.

In addition, it is not deemed that steps described in the present invention should be conducted in order. For example, terms such as a first step and a second step do not mean that the first step should be conducted before the second step.

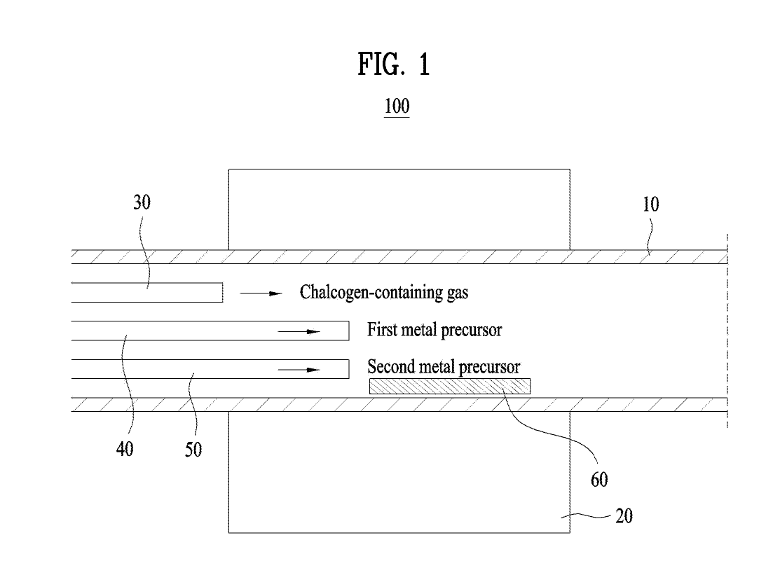

FIG. 1 is a schematic view illustrating an example of a process of manufacturing a doped metal chalcogenide thin film according to the present invention.

As shown in FIG. 1, a gasified first metal precursor and a gasified second metal precursor react with a chalcogen-containing gas using a growth apparatus 100 and are subjected to vapor deposition to form a metal chalcogenide thin film.

In this case, the second metal powder may function as a dopant of the metal chalcogenide thin film. In this case, the first metal powder may be referred to as a “target metal” and the second metal powder may be referred to as a “dopant metal”. The concentration of doping with the second metal precursor may be controlled by a ratio between the first metal precursor and the second metal precursor.

The process of forming the doped metal chalcogenide thin film may include supplying gasified first and second metal precursors, supplying a chalcogen-containing gas and reacting the gasified metal precursors with the chalcogen-containing gas on a growth substrate under a first temperature condition to form a thin film. These steps may be performed in different orders or simultaneously.

FIG. 1 schematically illustrates a process of growing a doped metal chalcogenide thin film using chemical vapor deposition (CVD) for growth of the thin film.

The growth apparatus 100 using such chemical vapor deposition includes a chamber 10 where a thin film is grown and a heater (or furnace) 20 to heat a growth area located in the chamber 10.

A substrate 60 for growth of the thin film is located in the growth area and tubes 30, 40 or 50, to which a source for growth of the thin film is supplied, are located at a side of the substrate 60.

The tube may include a first tube 30 to supply a chalcogen-containing gas, a second tube 40 to supply the gasified first metal precursor and a third tube 50 to supply the gasified second metal precursor.

The chamber 10 and at least one of the tubes 30, 40 and 50 may include quartz.

In addition to the aforementioned elements, the growth apparatus 100 may further include elements such as a mass flow controller (MFC), a furnace, a pump and a controller.

The growth substrate 60 may be a silicon (Si) substrate and a metal chalcogenide thin film may be formed on the silicon (Si) substrate. In this case, silicon oxide (SiO₂) may be disposed on the silicon substrate. That is, silicon oxide may be further disposed between the silicon substrate and the doped metal chalcogenide thin film formed by the manufacturing method of the present invention.

The growth substrate 60 may include, in addition to a silicon substrate, at least one of SiO₂, BN, Ge, GaN, AlN, GaP, InP, GaAs, SiC, Al₂O₃, LiAlO₃, MgO, glass, quartz, sapphire, graphite and graphene.

An example in which hydrogen sulfide (H₂S) is used as the chalcogen-containing gas has been shown, but at least one gas of S₂, Se₂, Te₂, H₂Se, and H₂Te may be used.

In addition, an additional carrier gas or atmosphere gas may be supplied through the entirety of an additional tube (not shown) or chamber 10.

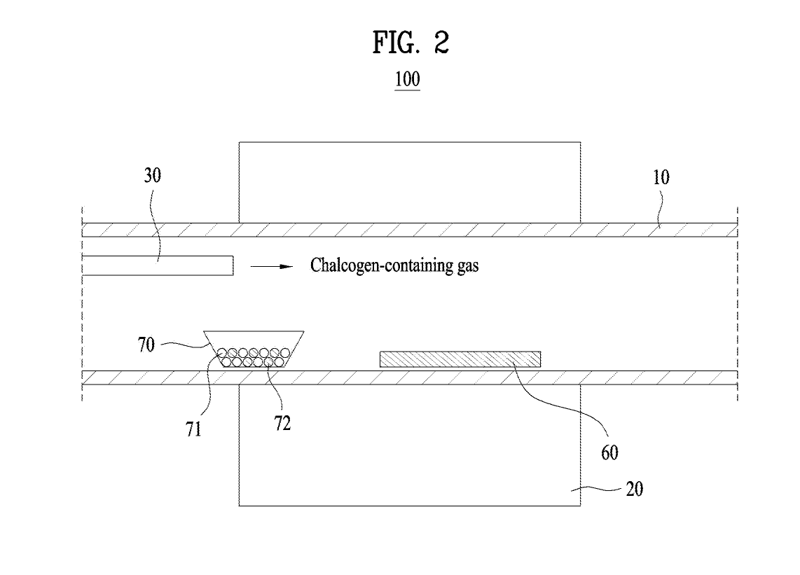

FIG. 2 is a schematic view illustrating another example of a process of manufacturing a doped metal chalcogenide thin film according to the present invention.

FIG. 2 shows a growth apparatus 100 using chemical vapor deposition (CVD) similar to FIG. 1, but the gasified first metal precursor and the gasified second metal precursor may be supplied by heating a metal powder.

That is, the first metal precursor and the second metal precursor may be formed by heating a first metal powder and a second metal powder, respectively, or a mixture thereof.

As such, the gasified first metal precursor and the gasified second metal precursor may be produced by heating a first metal powder 71 and a second metal powder 72 in a boat 70.

That is, gasified radicals are produced by heating the first metal powder 71 and the second metal powder 72, and then moved by a carrier gas to a growth area in which the substrate 60 is disposed.

In this case, the carrier gas may be selected from various gases and may, for example, be argon (Ar) gas. That is, growth of a thin film may be carried out under an argon gas atmosphere.

Other conditions may be the same as those described with reference to FIG. 1.

A doped metal chalcogenide thin film having a single or multiple layers may be formed depending on reaction temperature and/or content ratio by reacting the gasified first metal precursor and the gasified second metal precursor with a chalcogen-containing gas using the growth apparatus 100 illustrated in FIG. 1 or 2.

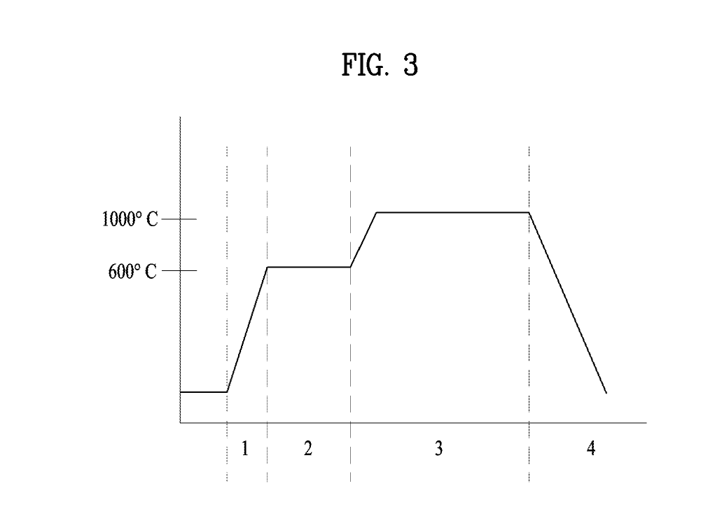

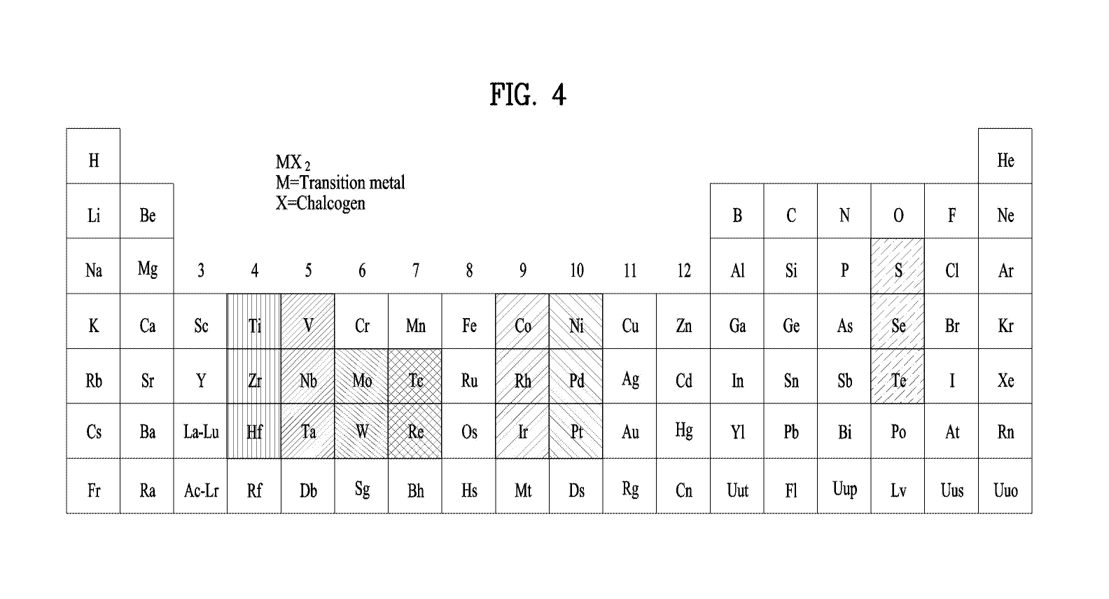

FIG. 3 is a graph showing an example of a process of forming a doped metal chalcogenide thin film according to the present invention. FIG. 4 shows the location of elements for forming the metal chalcogenide thin film on the periodic table.

FIG. 4 shows elements which may form a metal chalcogenide thin film by bonding between a transition metal (M) and chalcogen (X). The metal chalcogenide thin film may be represented by a formula such as MX₂.

Hereinafter, a method of manufacturing the chalcogenide thin film will be described with reference to FIGS. 1 to 4.

Here, an example in which the growth of the thin film is carried out in a growth apparatus 100 using chemical vapor deposition shown in FIG. 1 or 2, and the gasified first metal precursor and the gasified second metal precursor are supplied by heating a metal powder will be described.

First, a metal precursor powder of a target metal (first metal) chalcogenide thin film and a powder of a dopant metal (second metal) are prepared.

In general, to obtain a p-doped metal chalcogenide thin film, the Group of the periodic table of the dopant metal (second metal) should be lower than the Group of the target metal (first metal).

On the other hand, to obtain an n-doped metal chalcogenide thin film, the Group of the periodic table of the dopant metal (second metal) should be higher than the Group of the target metal (first metal) (see FIG. 4).

For example, when the target metal (first metal) belongs to Group VI, the first metal precursor may be Mo or W. That is, a metal powder of Mo and W may be used.

In this case, when the second metal precursor includes any one of Tc and Re, it may be a metal precursor serving as an n-type dopant, and when the second metal precursor includes any one of V, Nb, Ta, Ti, Zr, Hf and Y, it may be a metal precursor serving as a p-type dopant.

That is, a metal powder of Tc or Re is prepared in order to dope with an n-type dopant, and a metal powder of any one of V, Nb, Ta, Ti, Zr, Hf and Y is prepared in order to dope with a p-type dopant.

Meanwhile, when the target metal belongs to Group V, the first metal precursor includes V, Nb or Ta, and the second metal precursor may include an n-type dopant including any one of Mo, W, Tc and Re, or a p-type dopant including any one of Ti, Zr, Hf and Y. That is, a powder composed of these metals is prepared.

In addition, when the target metal belongs to Group IV, the first metal precursor may include Ti, Zr or Hf, and the second metal precursor may include an n-type dopant including any one of V, Nb, Ta, Mo, W, Tc and Re, or a p-type dopant including any one of Sc and Y. That is, a powder composed of these metals is prepared.

Meanwhile, when the target metal belongs to Group VII, the first metal precursor may include Tc or Re, and the second metal precursor may include an n-type dopant including any one of Fe, Ru and Os, or a p-type dopant including any one of Mo, W, V, Nb, Ta, Ti, Zr and Hf. That is, a powder composed of these metals is prepared.

The amounts of the determined target metal (first metal) powder 71 and dopant metal (second metal) powder 72 are determined and mixed. In this case, a mix ratio may be determined depending on doping concentration and vapor pressures of the metal powders may also be considered.

Then, the mixed metal powders 71 and 72 are put in a boat 70 and disposed in the growth apparatus 100.

As a result, the desired substrate 60 is disposed in a growth area in the growth apparatus 100 and the temperatures of the substrate 60 and the boat 70 are increased while feeding an atmosphere gas (for example, argon gas) (step 1 of FIG. 3).

When the temperature reaches a thin film formation temperature (for example, 600° C.), a chalcogen-containing gas is supplied to form a doped metal chalcogenide thin film (step 2).

Upon formation of the thin film, gasification of the first metal powder 71 and the second metal powder 72 may be carried out at 300 to 1,000° C. In addition, synthesis of the metal chalcogenide thin film may be carried out at 300 to 1,000° C. More specifically, synthesis of the metal chalcogenide thin film may be carried out at 300 to 850° C.

For example, molybdenum oxide (MoO₃) has a melting point of about 795° C., whereas growth of the thin film is carried out at a temperature lower than the melting point. For example, growth of a molybdenum sulfide (MoS₂) thin film from hydrogen sulfide (H₂S) as a chalcogen-containing gas and molybdenum oxide may be carried out at 600° C.

In the case of using plasma enhanced CVD (PECVD) or the like, a temperature of gasifying the metal powder 21 and a temperature of synthesizing the metal chalcogenide thin film 50 may be lowered to 100° C.

Then, heat treatment is conducted at a temperature higher than the growth temperature (for example, 1,000° C.) (step 3). During this heat treatment, a chalcogen-containing gas may be supplied. Such heat treatment may be conducted at a temperature of 800 to 1,200° C.

Then, cooling to room temperature (step 4) may be conducted.

All of these steps may be conducted under an argon gas atmosphere.

Through such a process, the doped metal chalcogenide thin film on the substrate 60 can be obtained.

As described above, the doped metal chalcogenide thin film can be formed by mixing the first metal precursor with the second metal precursor, gasifying the mixture and reacting the gasified first and second metal precursors with a chalcogen-containing gas.

Accordingly, a substituted and doped high-quality metal chalcogenide thin film can be obtained.

As mentioned above, a ratio between the first metal precursor and the second metal precursor can be easily controlled and the doping concentration can be easily controlled depending on the ratio.

Meanwhile, although embodiments according to the present invention disclosed in the specification and the drawings have been provided as specific examples for illustrative purposes, they should not be construed as limiting the scope of the present invention. It will be apparent to those skilled in the art that various modifications and variations can be made in the present invention without departing from the spirit or scope of the invention.

### INDUSTRIAL APPLICABILITY

According to the present invention, because a metal chalcogenide thin film is formed by vapor reaction and a gas chalcogen source is used, a high quality thin film can be obtained and a uniform thin film with a wide area can be synthesized.

In addition, a doped metal chalcogenide thin film can be formed by mixing the first metal precursor with the second metal precursor, gasifying the mixture and reacting the gasified first and second metal precursors with a chalcogen-containing gas.

1. A method of manufacturing a doped metal chalcogenide thin film comprising:
supplying a gasified first metal precursor;
supplying a gasified second metal precursor;
supplying a chalcogen-containing gas; and
reacting the first metal precursor and the second metal precursor with the chalcogen-containing gas on a growth substrate under a first temperature condition to form a thin film.

2. The method according to claim 1, wherein the gasified first metal precursor and the gasified second metal precursor are formed by heating a first metal powder and a second metal powder, respectively, or a mixture thereof.

3. The method according to claim 2, wherein the second metal powder functions as a dopant of the metal chalcogenide thin film and the doping concentration is controlled by a molar ratio of the first metal powder and the second metal powder.

4. The method according to claim 1, wherein the first metal precursor comprises Mo or W, and the second metal precursor comprises an n-type precursor including Tc and Re, or a p-type precursor including any one of V, Nb, Ta, Ti, Zr, Hf and Y.

5. The method according to claim 1, wherein the first metal precursor comprises V, Nb or Ta, and the second metal precursor comprises an n-type precursor including any one of Mo, W, Tc and Re, or a p-type precursor including any one of Ti, Zr, Hf and Y.

6. The method according to claim 1, wherein the first metal precursor comprises Ti, Zr or Hf, and the second metal precursor comprises an n-type precursor including any one of V, Nb, Ta, Mo, W, Tc and Re, or a p-type precursor including any one of Sc and Y.

7. The method according to claim 1, wherein the first metal precursor comprises Tc or Re, and the second metal precursor comprises an n-type precursor including any one of Fe, Ru and Os, or a p-type precursor including any one of Mo, W, V, Nb, Ta, Ti, Zr and Hf.

8. The method according to claim 1, further comprising:
conducting heat treatment under a second temperature condition higher than the first temperature condition.

9. The method according to claim 8, wherein the first temperature condition is 300 to 850° C., and the second temperature condition is 850 to 1,200° C.

10. The method according to claim 8, wherein the heat treatment is carried out under a chalcogen-containing gas atmosphere.

11. The method according to claim 1, wherein the chalcogen-containing gas comprises at least one of S₂, Se₂, Te₂, H₂S, H₂Se, and H₂Te.

12. A method of manufacturing a doped metal chalcogenide thin film comprising:
supplying a gasified first metal precursor;
supplying a gasified second metal precursor which belongs to a higher or lower Group on the periodic table than the first metal;
supplying a chalcogen-containing gas; and
reacting the first metal precursor and the second metal precursor with the chalcogen-containing gas on the growth substrate under a first temperature condition to form a thin film.

13. The method according to claim 12, wherein the gasified first metal precursor and the gasified second metal precursor are formed by heating a first metal powder and a second metal powder, respectively, or a mixture thereof.

14. The method according to claim 13, wherein the second metal powder functions as a dopant of the metal chalcogenide thin film and the doping concentration is controlled by a molar ratio of the first metal powder and the second metal powder.

15. The method according to claim 12, wherein the first metal precursor comprises Mo or W, and the second metal precursor comprises an n-type precursor including Tc and Re, or a p-type precursor including any one of V, Nb, Ta, Ti, Zr, Hf and Y.

16. The method according to claim 12, wherein the first metal precursor comprises V, Nb or Ta, and the second metal precursor comprises an n-type precursor including any one of Mo, W, Tc and Re, or a p-type precursor including any one of Ti, Zr, Hf and Y.

17. The method according to claim 12, wherein the first metal precursor comprises Ti, Zr or Hf, and the second metal precursor comprises an n-type precursor including any one of V, Nb, Ta, Mo, W, Tc and Re, or a p-type precursor including any one of Sc and Y.

18. The method according to claim 12, further comprising:
conducting heat treatment under a second temperature condition higher than the first temperature condition.

19. The method according to claim 18, wherein the heat treatment is carried out under a chalcogen-containing gas atmosphere.

20. The method according to claim 12, wherein the chalcogen-containing gas comprises at least one of S₂, Se₂, Te₂, H₂S, H₂Se, and H₂Te.
